(19) United States
(12) Patent Application Publication
(10) Pub. No.: US 2008/0173541 A1
(43) Pub. Date: Jul. 24, 2008

(54) Target designs and related methods for reduced eddy currents, increased resistance and resistivity, and enhanced cooling

(76) Inventors: Eal Lee, Milpitas, CA (US); Werner Hort, Cranberry, PA (US); Janine Kardokus, Veradale, WA (US); Susan D. Strothers, Spokane, WA (US); Kim Jaeyeon, Spokane, WA (US)

Correspondence Address: BUCHALTER NEMER, 18400 VON KARMAN AVE., SUITE 800, IRVINE, CA, 92612, US

(21) Appl. No.: 11/656,705

(22) Filed: Jan. 22, 2007

(51) Int. Cl. C23C 14/00; B23P 11/00

(52) U.S. Cl. 204/298.12; 29/428

(57) ABSTRACT

A sputtering target is described herein that comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature increases the resistance, resistivity or a combination thereof of the core backing component. Methods of forming a sputtering target are also described that comprises: a) providing a target surface component comprising a surface material; b) providing a core backing component comprising a backing material and having a coupling surface and a back surface; c) providing at least one surface area feature coupled to or located in the back surface of the core backing component, wherein the surface area feature increases the resistance, resistivity or a combination thereof of the core backing component; and d) coupling the surface target material to the coupling surface of the core backing material.

### FIELD OF THE SUBJECT MATTER

The field of the subject matter is design and use of sputtering targets that have reduced eddy currents, increased resistance and/or resistivity, and enhanced cooling.

### BACKGROUND OF THE SUBJECT MATTER

Electronic and semiconductor components are used in ever-increasing numbers of consumer and commercial electronic products, communications products and data-exchange products. Examples of some of these consumer and commercial products are televisions, computers, cell phones, pagers, palm-type or handheld organizers, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, modified and improved.

In order to improve the process of depositing a layer of material, the surface and/or material composition must be measured, quantified and defects or imperfections detected. In the case of the deposition of a layer or layers of material, its not only the actual layer or layers of material that should be monitored but also the material and surface of that material that is being used to produce the layer of material on a substrate or other surface that should be monitored. For example, when depositing a layer of metal onto a surface or substrate by sputtering a target comprising that metal, the target must be monitored for uneven wear, target deformation, target deflection and other related conditions. Uneven wear of a sputtering target is inevitable, a function of the magnet design and will reduce the lifetime of the target, and in some cases result in little or no deposition, of the metal on the surface of a substrate.

In sputtering target apparatus, magnetron sputtering relies on the ability to control the plasma with a magnetic field, which is usually achieved by arranging magnets at the back of the target and rotating them at high speeds during the sputtering process, as shown in Prior Art FIGS. 1A and 1B. In FIG. 1A, the chamber 105 contains a sputtering target 110, a set of rotating magnets 190, an anode 120, a silicon wafer or other substrate 130, a power supply 140. The rotating magnets 190 are powered by a rotary motor 147. Water 145 is directed into the system for cooling purposes. Process gas 160 enters the chamber and heated gas 170 interacts with the surface 130. A pump 180 pulls gas out of the system to create a vacuum. Dense plasma 155 is shown, which is “surrounded” by a magnetic field 150. FIG. 1 B shows a closer view of the sputtering target 110 area. Note that eddy currents 152 are part of the magnetic field 150.

Researchers and technicians take extreme care when selecting the specific arrangement of these magnets to achieve a uniform deposition of the sputtered material on the substrate, especially as wafers and electronic parts get smaller and thinner. Increasing the rotational speed of the magnets is beneficial to the deposition of uniform films, and to this end, rotational speeds of the magnetrons have increased over time.

Recently, it has been observed that for some combination of sputtering tools and highly conductive (electrical) materials that the rotational speeds are limited by the ability to light and/or maintain the plasma at higher speeds. It is helpful to understand the fundamental concept of Maxwell's equations in conductors:

$$∇ \times B = μ σ E + μɛ \frac{\partial E}{\partial t}$$

$$∇ \times E = - \frac{\partial B}{\partial t}$$

E: Electric field

B: Magnetic Field

μ: Permeability of the medium

ε: Permittivity of the medium

σ: Conductivity of the medium

As shown by these equations, the temporal changes in the magnetic field induce an electric field perpendicular to the B-field changes. The induced E-field causes a circulating flow of electrons in electrically conducting materials. These currents are referred to as eddy currents. The magnetic field induced by these eddy currents is oriented in such a way as to oppose the changes in the original B-field (Lenz' Law). This effect is believed to be the cause of the problems related to lighting and maintaining the plasma at higher rotational speeds. This can also be illustrated by depictions of Faraday's Law in FIG. 2.

In FIG. 2, the changing magnetic flux (Φ=BA) induces a voltage (emf, ε) or Eddy current (I_{eddy}). Eddy currents increase with the rate of magnetic flux change (ΔΦ/Δt). A in this case refers to the area. Also, one must review Lenz' Law, where Eddy currents induce a secondary magnetic field (B′) that opposes the primary magnetic field (Bₒ). These eddy currents induce magnetic fields that oppose the primary magnetic field, reducing effective magnetic field strength and weakening plasma density. This adverse effect increases with increasing the rotational speed of magnets, and often results in plasma ignition failure, particularly for a system that employs very strong magnets and low pressure such as self-ionizing plasma (SIP) systems. Such effect becomes more pronounced for targets with high electrical conductivity such as copper. For this reason, an alloyed backing plate is often used to increase the resistivity of a target (e.g., Cu target with more resistive Al or Cu—CrSiNi backing plate) At too low rotational speed, the eddy current effect is reduced and thus it may be possible to generate the plasma, but the intended plasma uniformity can be compromised at slow rotational speed.

Reducing the target thickness removes electrically conductive material and thus reduces eddy currents. Reducing target thickness has additional benefits, as shown in FIG. 3 and by the equation below:

$$\frac{Δ Q}{Δ t} = - kA \frac{Δ T}{Δ x}$$

$$\frac{Δ Q}{Δ t} = Energy Flow ( calories \text{/} sec )$$

$$k = Thermal Conductivity ( cal \text{-} cm \text{/} {cm}^{2} \text{-} sec \text{-} {}^{°} C . )$$

$$A = Target surface area ( {cm}^{2} )$$

$$\frac{Δ T}{Δ x} = Thermal Gradient ( {}^{°} C . \text{/} cm )$$

First, since the temperature differential across the target is proportional to the target thickness, it reduces the surface temperature. As shown, among the four factors above, the thickness is probably the most sensitive parameter to review for target cooling. Reducing the thickness of the target not only reduces the eddy currents but also increases the operating voltage because of the increased resistance with decreasing target thickness (reduced conduction path). The radius of spiraling electron increases with increasing voltage, which widens the width of target erosion track and thus improves the usage of target material resulting in extended target life. As stated earlier, the primary enhancement of the plasma is due to the reduced eddy currents, which also widens the erosion track width and extends the target life.

In addition to resolving the issue of eddy currents, additional problems will occur when the sputtering target overheats because of the bombardment of the target with argon ions at a high power, which can often exceed a few to several tens of kilo-Watts. Such a high power can melt the target without proper cooling and/or degrade the mechanical stability of the target if the cooling is inefficient. There are four generally accepted factors that control the cooling of a sputtering target: a) thermal conductivity, b) cooling water flow rate, c) cooling surface area and d) the thickness of a target.

Cooling of the sputtering target can be improved by using a backing plate with a high thermal conductivity, increasing the cooling surface area, controlling the flow pattern of the coolant, improving coolant circulation with the rotating magnets and/or reducing the thickness of the target material. In the past, various attempts have been made to improve the cooling efficiency via various design modifications, but the most important “thickness factor” has not been considered for heat reduction.

Therefore, in order to maximize the mechanical stability of sputtering targets while at the same time maximizing sputtering performance, researchers and technicians should review not only the magnetic fields, but also the cooling efficiency of the sputtering target.

Gardell et al. (U.S. Pat. No. 5,628,889) discloses a high-power capacity magnetron cathode with an independent cooling system for the magnet array support plate. In Gardell, a horizontal magnet array fluid control surface is physically attached to the magnet array support plate. The fluid control surface or device is not integrated into the materials of the support plate, the magnet array or the cathode materials. Therefore, there are more working parts, additional layers of complexity in the design and use of the magnetron cathode, and additional work for workers who handle repair and replacement of parts.

During conventional manufacturing and/or use of either electronic and/or semiconductor components, the wear of materials and targets cannot be easily checked, because such checks either require that the operation be interrupted, or that an experienced operator be at hand or on an equipment monitoring schedule, both of which are costly. This often results in scheduled (rather than on demand) replacement of such materials, which again leads to costly waste of material, especially if the material is expensive to obtain or replace or if the material is not compromised in the first place.

Prior Art FIGS. 4 and 5 show a new conventional target 400 and the same target 500, which has shown an uneven wear pattern 520 after a period of use. Conventional targets are also subject to bowing or deformation, shown in the warpage profiles of FIGS. 6 and 7, when the target is heated to the point where bowing and/or deformation can occur and when the cooling system or method is not utilized effectively or is not efficient.

To this end, it would be desirable to develop and utilize a target design that will a) exhibit increased resistance; b) reduce the deformation of the target in service; c) reduce the eddy currents; d) provide ease of use as compared to conventional systems; e) minimize unwanted deflection of sputtered atoms and molecules; and f) be effective for both monolithic (unibody design), three-dimensional and conventional sputtering targets that have a target coupled to a backing plate.

### SUMMARY OF THE INVENTION

A sputtering target is described herein that comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature increases the resistance, resistivity or a combination thereof of the core backing component.

Methods of forming a sputtering target are also described that comprises: a) providing a target surface component comprising a surface material; b) providing a core backing component comprising a backing material and having a coupling surface and a back surface; c) providing at least one surface area feature coupled to or located in the back surface of the core backing component, wherein the surface area feature increases the resistance, resistivity or a combination thereof of the core backing component; and d) coupling the surface target material to the coupling surface of the core backing material.

### BRIEF DESCRIPTION OF THE FIGURES

Prior Art FIG. 1 shows a conventional sputtering chamber assembly.

FIG. 2 shows a conventional depiction of Faraday's Law.

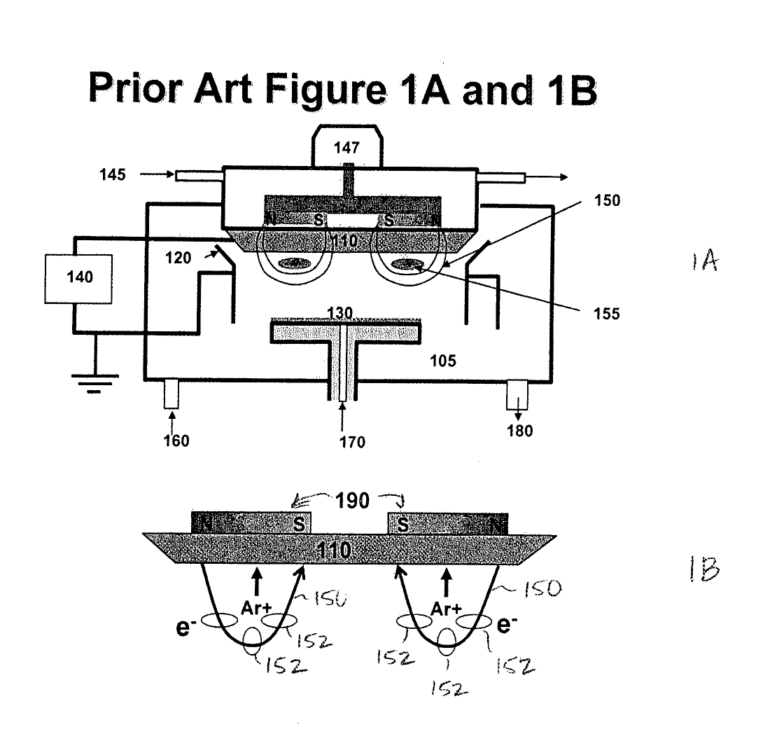

FIG. 3 shows a graphical depiction of the thickness parameter and its influence over eddy current formation.

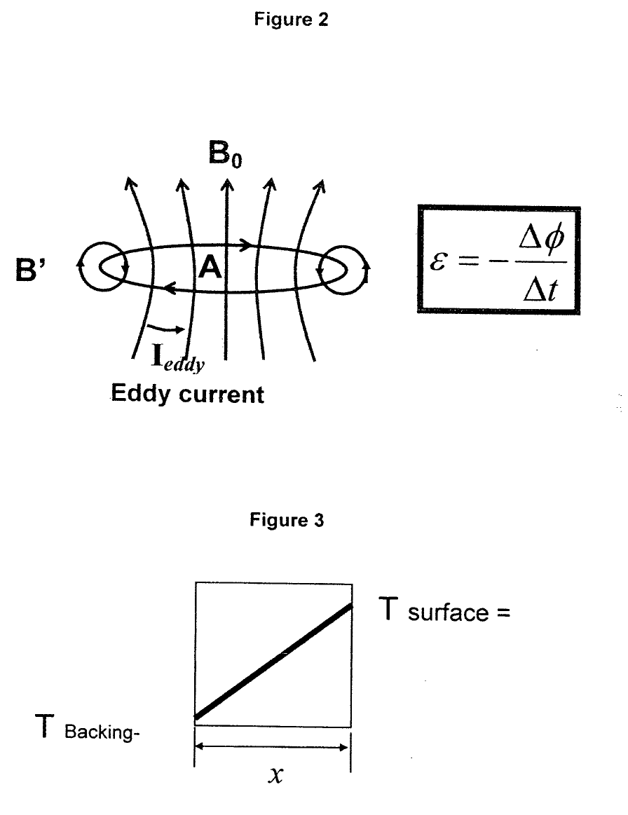

Prior Art FIG. 4 shows a photo of conventional sputtering target assembly.

Prior Art FIG. 5 shows a photo of a non-uniformly worn conventional sputtering target assembly.

FIG. 6 shows a conventional warpage profile.

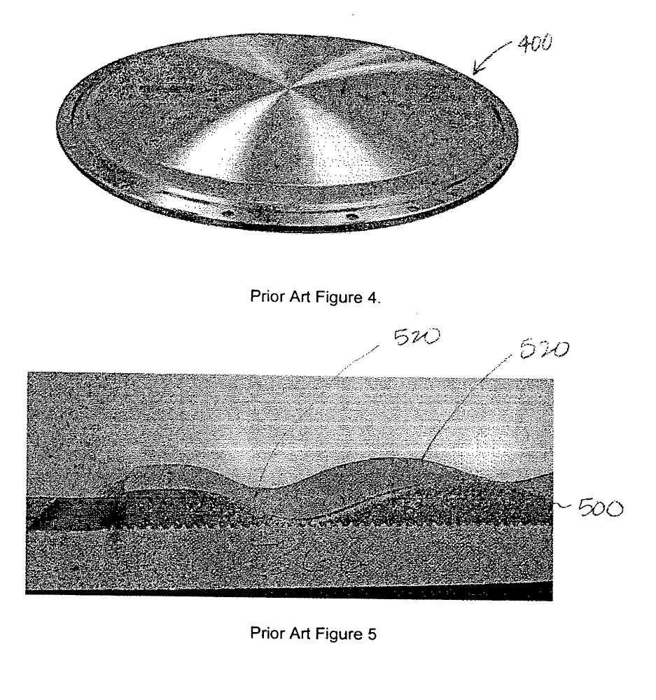

FIG. 7 shows a conventional warpage profile.

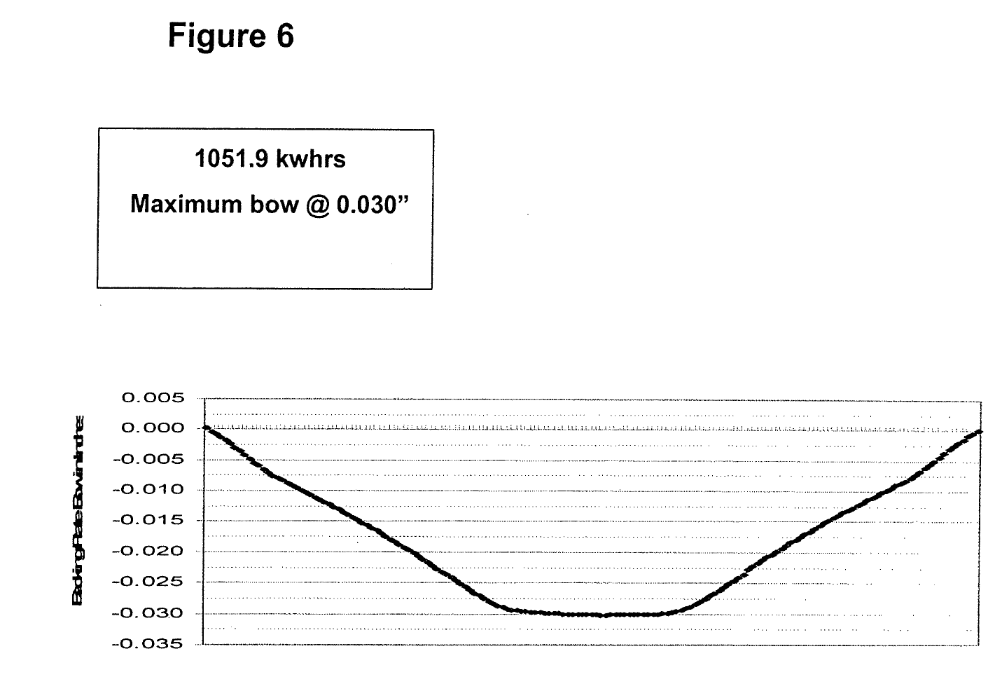

FIGS. 8A and 8B show a conventional sputtering target design and a contemplated sputtering target design with erosion profile modification.

FIG. 9 shows a general method for utilizing a contemplated system.

FIG. 10 shows current and voltage data for a contemplated target.

FIGS. 11 shows resistivity data versus the length of time in kW-hours of target use.

FIG. 12 shows film thickness data versus the length of time in kW-hours of target use.

FIG. 13 shows the film uniformity versus the target life for various targets.

FIG. 14 shows reflectivity versus T-S spacing for a conventional target.

FIG. 15 shows reflectivity versus T-S spacing for a contemplated target.

FIG. 16 shows the deposition rate versus T-S spacing at various stages of a target's life for a conventional target.

FIG. 17 shows the deposition rate versus T-S spacing at various stages of a target's life for a contemplated target.

FIG. 18 shows additional data for deposition rate versus target life.

FIG. 19 shows the deposition yield versus target erosion.

FIG. 20 adds additional information for contemplated targets by showing the deposition rate versus power for standard and contemplated targets.

FIG. 21 shows a schematic of a sputtering apparatus utilizing a contemplated target. It is useful to note that the deposition profile widens with the use of contemplated targets, and thus leads to deposition on the clamp rings and shields.

Table 1 shows a summary of the properties of conventional targets versus some of those contemplated herein.

Table 2 shows the data collected for the spacing matrix study.

### DETAILED DESCRIPTION

A sputtering target and related cooling system has been developed and is described herein that a) exhibits increased resistance and/or resistivity; b) reduces the deformation of the target in service; c) reduces the eddy currents; d) provides ease of use as compared to conventional systems; e) minimizes unwanted deflection of sputtered atoms and molecules; and f) is effective for both monolithic (unibody design), three-dimensional and conventional sputtering targets that have a target coupled to a backing plate.

To this end, a sputtering target and/or sputtering target assembly comprises: at least one surface area feature coupled to or located in the back surface of the core backing component, wherein the at least one surface area feature increases the resistance, resistivity or a combination thereof of the core backing component. The increased resistance by the reduced conduction path cross-section feature results in less resulting eddy currents during the operation of the sputtering target assembly. The resistivity increase is a result of the modified composition of the back surface of the core backing component.

The at least one surface area feature, which is designed to increase the resistance, resistivity or a combination thereof of the core backing component, is different from a conventional surface area feature on a conventional sputtering target. As used herein, the phrase “conventional surface area feature” means those surface area features that are not intentionally modified in order to increase resistance and/or resistivity of the feature. The at least one surface area feature contemplated herein comprise altered microstructures, microgrooves, slits or cracks, erosion profile modifications and combinations thereof. It should be understood that all of these modified surface area features are intended to increase the resistance and/or resistivity at the back of the sputtering target and reduce the volume of material in which eddy current can be induced.

One contemplated surface area feature is an altered microstructure, which can be produced a number of ways, including alloying the back surface of the core backing component, introducing deformation or materials to the surface, or a combination thereof. In other contemplated embodiments, the microstructure of the back surface can be altered a) by coating—in full or in part—the back surface by utilizing a suitable coating process, such as electro-plating or vapor deposition, which may be followed by an annealing process that allows the coating to diffuse into the core backing component of the target; b) by ion-implantation (another alloying process); c) shot peening or any other suitable deformation process; d) mechanical alloying methods where small particles of alloying elements hit the back surface at a high speed; or e) a combination thereof.

Another contemplated surface area feature is obtained by introducing microgrooves, slits and cracks into the back surface of the core backing component, which changes the geometry of the target in order to increase the resistance of the back surface. This method, along with erosion profile modification, serves to increase resistance in a similar way as reducing the cross-section of a resistor. This particular surface area feature modification is particularly advantageous because eddy currents are commonly used during non-destructive testing to detect cracks or small voids in conductive materials. In this type of testing, a probe generates a fast varying magnetic field which generates eddy currents in the tested material. If cracks are present, the flow of the currents is disrupted and the eddy current instrument detects an increased resistance. By applying this concept to the problem of the reduction of eddy currents in the core backing component, one can intentionally introduce microgrooves, slits and cracks—in either a random or patterned fashion—to function as “eddy current disrupters”. With respect to whether its advantageous to introduce either random, patterned or a combination thereof of microgrooves, slits and cracks in to the core backing material, this decision usually depends on the specifics of the magnetrons and on the desired effects of the fluid flow behind the core backing component. One of ordinary skill in the art of sputtering target assemblies should understand this concept after reviewing this disclosure and understand how to modify the surface area feature based on the specifics of the magnetrons and on the desired effects of the fluid flow behind the core backing component. One method of modifying the surface area feature of the core backing component in this fashion is shown in PCT Application Serial No.: PCT/US02/06146 or Publication No.: WO 03/000950 entitled “Morphologically Tailored Omni-Focal Target”, which was filed on Feb. 20, 2002, is commonly-owned, and which is incorporated herein in its entirety by reference.

In some embodiments, the resistance, resistivity or a combination thereof of the core backing component is increased as compared with the resistance, resistivity or a combination thereof of a conventional core backing component. In other embodiments, the resistance, resistivity or a combination thereof of the core backing component is increased by at least 10% as compared with the resistance, resistivity or a combination thereof of a conventional core backing component. In yet other embodiments, the resistance, resistivity or a combination thereof of the core backing component is increased by at least 50% as compared with the resistance, resistivity or a combination thereof of a conventional core backing component.

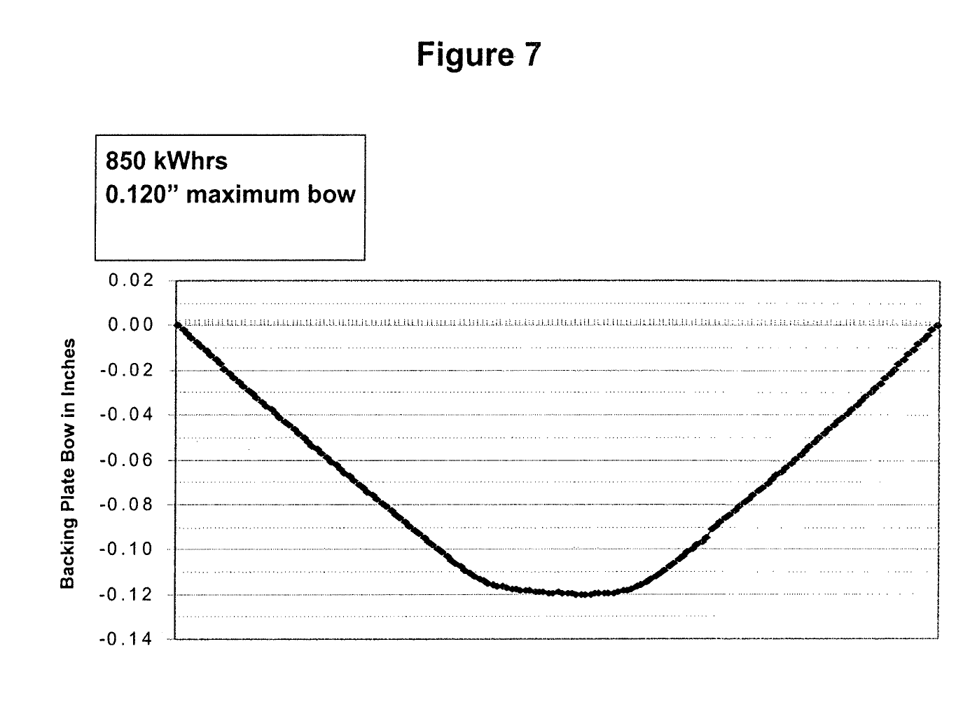

Yet another contemplated surface area feature is to tailor the surface area feature such that it mirrors the erosion profile of the target surface—what is called erosion profile modification, which is shown in FIGS. 8A and 8B. A conventional target 800 is shown in FIG. 8A having a surface 810. In FIG. 8B, this surface 810 is now exhibiting an erosion 820 that mirrors the erosion profile 830 shown in FIGS. 8A and 8B. As background for this particular modification, in DC magnetron sputtering, a high flux of Ar+ ions is bombarding the target at high power, often exceeding a few to several tens of kilo-watts. Such a high power can melt the target without proper cooling, or degrade the mechanical stability if cooling is insufficient. Four main factors control the cooling, namely thermal conductivity, cooling water flow rate, cooling surface area, and the thickness of a target. Cooling can be improved by using a backing plate with high thermal conductivity, increasing cooling surface area, controlling the flow pattern of coolant, improving coolant circulation with the rotating magnets, and lastly by reducing the thickness of the target material. Among these factors, the thickness is the most sensitive factor that controls the cooing. In the past, various attempts have been made to improve the cooling efficiency via various design modification, but the most important—the thickness factor—has not been considered for heat reduction.

Tailoring the surface area feature of the core backing material with reduced thickness accomplishes many desirable goals. First, there is a noticeable reduction in the amount and degree of eddy currents, but also, this modification improves cooling as well as the mechanical stability of the target. Conventional targets have a flat or slightly sloped backing plate (BP) but overall target thickness is fairly uniform. When the target is heated, the lateral thermal expansion causes the target to warp to relieve the stress. Target erosion is determined mainly by the magnet configuration and its rotating pattern, such that erosion is not uniform but produces circular grooves in a wave form if viewed in cross-section. The fastest eroding groove determines the target life, although the materials in the slow-eroding area are unused. In a new design, the back-side of target surface is pre-grooved following the erosion profile, such that non-eroding area is thinner whereas the eroding area remains thicker. This design not only improves a cooling efficiency by reducing the target thickness but also improve the mechanical stability by relieving the stress into the area where the material is removed.

Any of the above modification techniques and approaches for improving the surface area feature of a sputtering target can be utilized alone or in combination with one another depending on the needs of the operator. What is exceptional about the subject matter described herein is that all of these approaches can be utilized on conventional sputtering targets, without altering the profile of sputtering surface.

Many targets, currently in use, are made of a backing plate for structural support and the actual target material that is to be deposited onto a substrate. The conventional approach is to reduce the resistance of the backing plate. Replacing high conductivity materials with low conductivity materials increases the resistivity, which means a composition change for the entire backing plate or replacing a fully annealed backing plate with a highly-worked backing plate. Changing the backing plate material will strongly affect other backing plate properties such as strength, heat capacity, thermal conductivity, etc., e.g. requiring a low conductivity backing plate severely limits the selection of available materials that fit into the required design parameter range or might result in one or more of the other properties being compromised. In addition, new materials require the development of new processes to bond the backing plate to the target material. By changing the resistivity in a surface layer by a surface treatment method, all of these material change issues are being avoided. The surface treatment process can be inserted close to the end of any of the current manufacturing processes. It can also be applied to monolithic targets, e.g. targets where the backing plate and target material are made from the same material and comprise one continuous piece of material. The materials choice in monolithic targets is dictated by the application of the target and can not be changed. For example, a monolithic (high purity) copper target used in semiconductor manufacturing, has very high electrical conductivity. The conventional approach cannot be pursued since the high purity copper is required for the semiconductor manufacturing process. However, changing the resistivity of the back of the target by introducing work (deformation) into a surface layer or by machining the back of the target (e.g. introducing a network or pattern of artificial “cracks”) will not change the composition of the target. Alloying a surface layer at the back of such a target is also permissible as long as the layer does not extend into any regions of the target materials that are to be used in the deposition process.

In some embodiments, the target surface component and the core backing component comprise the same material as the target material. In yet other embodiments, the target surface component arid the core backing component are coupled such that they form a monolithic sputtering target and/or sputtering target assembly.

Methods of forming a sputtering target are also described that comprises: a) providing a target surface component comprising a surface material; b) providing a core backing component comprising a backing material and having a coupling surface and a back surface; c) providing at least one surface area feature coupled to or located in the back surface of the core backing component, wherein the at least one surface area feature increases the resistivity of the core backing component; and d) coupling the surface target material to the coupling surface of the core backing material.

Sputtering targets and sputtering target assemblies contemplated herein comprise any suitable shape and size depending on the application and instrumentation used in the PVD process. Sputtering targets contemplated herein also comprise a target surface component and a core backing component (which can include a backing plate), wherein the target surface component is coupled to the core backing component through and/or around a gas chamber or gas stream. As used herein, the term “coupled” means a physical attachment of two parts of matter or components (adhesive, attachment interfacing material) or a physical and/or chemical attraction between two parts of matter or components, including bond forces such as covalent and ionic bonding, and non-bond forces such as Van der Waals, electrostatic, coulombic, hydrogen bonding and/or magnetic attraction. The target surface material and core backing material may generally comprise the same elemental makeup or chemical composition/component, or the elemental makeup and chemical composition of the target surface material may be altered or modified to be different than that of the core backing material. In several embodiments, the target surface material and the core backing material comprise the same elemental makeup and chemical composition. As mentioned, the term “coupled” may mean that there is a bond force or adhesive force between the constituents of the sputtering target and/or sputtering target assembly, such that the sputtering target and/or sputtering target assembly is monolithic.

The target surface component is that portion of the target that is exposed to the energy source at any measurable point in time and is also that part of the overall target material that is intended to produce atoms and/or molecules that are desirable as a surface coating. The target surface material comprises a front side surface and a back side surface. The front side surface is that surface that is exposed to the energy source and is that part of the overall target material that is intended to produce atoms and/or molecules that are desirable as a surface coating. The back side surface or back surface is that surface that is coupled to the core backing component. The target surface component comprises a target material and that material may be any material that is suitable for forming a sputtering target. In some embodiments, the target surface component comprises a three-dimensional target surface, such as a target surface that is concave, convex or has some other unconventional shape. It should be understood that the target surface component, no matter what the shape of the component is, is the portion of the target that is exposed to the energy source at any measurable point in time and is also that part of the overall target material that is intended to produce atoms and/or molecules that are desirable as a surface coating.

The core backing material is designed to provide support for the target surface component and material and to possibly provide additional atoms in a sputtering process or information as to when a target's useful life has ended. For example, in a situation where the core backing material comprises a material different from that of the original target surface material, and a quality control device detects the presence of core material atoms in the space between the target and the wafer, the target may need to be removed and retooled or discarded altogether because the chemical integrity and elemental purity of the metal coating could be compromised by depositing undesirable materials on the existing surface/wafer layer.

In some embodiments, it would also be ideal to include a sensing system that would a) comprise a simple device/apparatus and/or mechanical setup and a simple method for determining wear, wear-out and/or deterioration of a surface or material; b) would notify the operator when maintenance is necessary, as opposed to investigating the quality of the material on a specific maintenance schedule; and c) would reduce and/or eliminate material waste by reducing and/or eliminating premature replacement or repair of the material. Devices and methods of this type are described in PCT Application Serial No.: PCT/US03/28832, which was filed on Sep. 12, 2003 and claims priority to U.S. Provisional Application Ser. No. 60/410540, which was filed on Sep. 12, 2002, both of which are commonly-owned and incorporated herein in their entirety.

The core backing component may comprise any material that is suitable for use in a sputtering target. The core backing component comprises a coupling surface that is designed to couple to the back surface of the target surface component. The core backing component also comprises a back surface that is designed to form the back of the sputtering target assembly, wherein the sputtering target assembly comprises a target surface component and a core backing component. In some embodiments, the core backing component comprises a backing plate.

Sputtering targets contemplated herein may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets are metals, metal alloys, conductive polymers, conductive composite materials, dielectric materials, hardmask materials and any other suitable sputtering material.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, ruthenium or a combination thereof. More preferred metals include copper, aluminum, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, tantalum, niobium, ruthenium or a combination thereof.

Examples of contemplated and preferred materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer or “blanket” layer of aluminum surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, ruthenium, tantalum, tin, zinc, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel, vanadium, tungsten titanium, tantalum ruthenium, copper manganese, germanium antimony telluride, copper gallium, indium selenide, copper indium selenide and copper indium gallium selenide and/or combinations thereof.

As far as other materials that are contemplated herein for sputtering targets, the following combinations are considered examples of contemplated sputtering targets (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof. In some embodiments, contemplated materials include those materials disclosed in U.S. Pat. No. 6,331,233, which is commonly-owned by Honeywell International Inc., and which is incorporated herein in its entirety by reference.

The core backing material and/or the target surface material constituents may be provided by any suitable method, including a) buying the core material and/or the surface material constituents from a supplier; b) preparing or producing the core material and/or the surface material constituents in house using chemicals provided by another source and/or c) preparing or producing the core material and/or the surface material constituents in house using chemicals also produced or provided in house or at the location.

The core material and/or the surface material constituents may be combined by any suitable method known in the art or conventionally used, including melting the constituents and blending the molten constituents, processing the material constituents into shavings or pellets and combining the constituents by a mixing and pressure treating process, and the like.

In some embodiments, namely the monolithic or unibody target configurations the surface target component and the core backing component may comprise the same target material. However, there are contemplated monolithic or unibody target configurations and designs where there is a material gradient throughout the sputtering target and/or sputtering target assembly. A “material gradient”, as used herein, means that the sputtering target or sputtering target assembly comprises at least two of the materials contemplated herein, wherein the materials are located in the sputtering target in a gradient pattern. For example, a sputtering target or target assembly may comprise copper and titanium. The surface target material of this same target may comprise 90% copper and 10%. titanium. If one viewed a cross-section of the target assembly or sputtering target, the amount or percentage of copper would decrease approaching the core backing component and the titanium percentage would increase approaching the core backing component. It is contemplated that the titanium percentage may decrease approaching the core backing material and the copper percentage may increase approaching the core backing component resulting in a 100% copper core backing component. A material gradient may be advantageous in order to detect wear of the target or to prepare subsequent layers that contain more or less of a certain component. It is also contemplated that a material gradient may comprise three or more constituents, depending on the needs of the layer, the component, the device and/or the vendor.

Another sputtering target and/or sputtering target assembly is described herein that comprises: a) a target surface component comprising a target material; b) a core backing component having a coupling surface and a back surface, wherein the coupling surface is coupled to the target surface component; and c) at least one surface area feature coupled to or located in the back surface of the core backing component, wherein the surface area feature comprises a subtractive feature, an additive feature or a combination thereof. The surface area feature comprises either a) a convex feature, a concave feature or a combination thereof; or b) an additive feature, a subtractive feature or a combination thereof.

As used herein, the phrases “convex feature”, “concave feature” or “a combination thereof” means that, in relation to each feature, that the feature is formed as part of the core backing component when the core backing component is itself formed. An example of these embodiments is where the core backing component is formed using a mold and the convex features, the concave features and/or the combination thereof of the features are part of the mold design. As used herein, the phrases “additive feature”, “subtractive feature” or “a combination thereof” mean that, in relation to each feature, that the feature is formed after the core backing component is formed. An example of these embodiments is where the core backing component is formed by any suitable method or apparatus and then the features are formed in or on the back surface or the coupling surface of the core backing component by a drill, a solder process or some other process or apparatus that can be used to either add (thus forming an additive feature) or subtract material (thus forming a subtractive feature) from the core backing component in a way so as to form the features.

As used herein, the phrases “additive feature”, “subtractive feature”, “convex feature” and “concave feature” are used to describe channels, microchannels, grooves, bumps and/or indentations can be produced in or on the core backing component of the sputtering target. The channels, microchannels, grooves, bumps, dimples, indentations or a combination thereof serve several beneficial needs, as described earlier, while at the same time increasing the surface area of the back of the target. As mentioned, by placing the channels, microchannels, grooves, bumps, dimples, indentations or a combination thereof along the entire back surface of or the center of the backing component, the cooling efficiency of the method of cooling and cooling fluid is increased over conventional side cooling. The channels, microchannels, grooves, bumps, dimples, indentations or a combination thereof may also be placed in or on the coupling surface of the core backing component.

The channels, microchannels, grooves, bumps, dimples, indentations or a combination thereof can be arranged or formed in or on the core backing component in any suitable shape, including concentric circles or grooves, a spiral configuration, a “side” facing chevron or a “center” pointing chevron.

In other embodiments, bumps or other configurations formed from core backing component material or another comparable material can be “built up” on the back surface or coupling surface of the core backing component in order to effectively increase the surface area of the core backing component and/or sputtering target assembly. It is further contemplated that the material used to build up a pattern or formation on the back of the core backing component can not only increase the surface area of the backing plate, but may also work in conjunction with the cooling device/method to further enhance the cooling effect on the target and/or reduce unwanted deflection of atoms and/or molecules from the target surface component of the sputtering target assembly.

The channels, microchannels, grooves, bumps, dimples, indentations or a combination thereof can be formed on the core backing component by using any suitable method or device, including machining, LASERs and the like, as previously described, resulting in at least one additive feature, at least one subtractive feature or a combination thereof. The core backing component may also be molded originally to include the channels, microchannels, grooves, bumps, dimples, indentations or a combination thereof resulting in at least one convex feature, at least one concave feature or a combination thereof, depending on the machinery of the vendor and the needs of the customer using the target.

For electronic and semiconductor applications and components, such as components and materials that comprise a layer of conductive material, the cooling device utilized for a sputtering target or other similar type of component that is used to lay down or apply the conductive layer of material is placed adjacent to the core backing component of the sputtering target and/or sputtering target assembly. In some contemplated embodiments, as mentioned earlier, the core backing component has channels, microchannels, grooves, bumps, dimples, indentations or a combination thereof formed in or on the coupling side or back side of the component and the cooling device or method not only contacts the core backing component, but also contacts the channels, microchannels, grooves, bumps, dimples, indentations or a combination thereof. If both the cooling enhancement method and/or device is being used in conjunction with the sensing/sensor device/method there will be channels located between the target and the backing plate for the sensing/sensor device and there will be channels, microchannels, grooves, bumps, dimples, indentations or a combination thereof formed in the backing plate that will increase the effective surface area of the backing plate of the target when in contact with a cooling fluid or cooling method. It should be appreciated, however, that the cooling enhancement method and/or device could be used alone without the sensing/sensor device and/or method.

In some embodiments, the incorporation of the channels, microchannels, grooves, bumps, dimples, indentations or a combination thereof will not only improve the cooling of the sputtering target and/or sputtering target assembly, but will also improve the cooling fluid flow along the core backing component. This improvement in cooling fluid flow can easily be attributed to and explained by conventional fluid mechanics principles.

The cooling fluid used in the cooling enhancement device and/or method may comprise any fluid that can be held at a particular temperature for the purpose of cooling a surface or can effect the cooling of a surface on contact. As used herein, the term “fluid” may comprise either a liquid or a gas. As used herein, any references to the term “gas” means that environment that contains pure gases, including nitrogen, helium, or argon, carbon dioxide, or mixed gases, including air. For the purposes of the present subject matter, any gas that is suitable to use in an electronic or semiconductor application is contemplated herein.

Contemplated sputtering targets described herein can be incorporated into any process or production design that produces, builds or otherwise modifies electronic, semiconductor and communication components. Electronic, semiconductor and communication components are generally thought to comprise any layered component that can be utilized in an electronic-based, semiconductor-based or communication-based product. Components described herein comprise semiconductor chips, circuit boards, chip packaging, separator sheets, dielectric components of circuit boards, printed-wiring boards, touch pads, wave guides, fiber optic and photon-transport and acoustic-wave-transport components, any materials made using or incorporating a dual damascene process, and other components of circuit boards, such as capacitors, inductors, and resistors.

Thin layers or films produced by the sputtering of atoms or molecules from targets discussed herein can be formed on any number or consistency of layers, including other metal layers, substrate layers, dielectric layers, hardmask or etchstop layers, photolithographic layers, anti-reflective layers, etc. In some preferred embodiments, the dielectric layer may comprise dielectric materials contemplated, produced or disclosed by Honeywell International, Inc. including, but not limited to: a) FLARE (polyarylene ether), such as those compounds disclosed in issued patents U.S. Pat. No. 5,959,157, U.S. Pat. No. 5,986,045, U.S. Pat. No. 6,124,421, U.S. Pat. No. 6,156,812, U.S. Pat. No. 6,172,128, U.S. Pat. No. 6,171,687, U.S. Pat. No. 6,214,746, and pending applications Ser. Nos. 09/197,478, 09/538,276, 09/544,504, 09/741,634, 09/651,396, 09/545,058, 09/587,851, 09/618,945, 09/619,237, 09/792,606, b) adamantane-based materials, such as those shown in pending application Ser. No. 09/545,058; Serial PCT/US01/22204 filed Oct. 17, 2001; PCT/US01/50182 filed Dec. 31, 2001; 60/345374 filed Dec. 31, 2001; 60/347195 filed Jan. 8, 2002; and 60/350187 filed Jan. 15, 2002;, c) commonly assigned U.S. Pat. Nos. 5,115,082; 5,986,045; and 6,143,855; and commonly assigned International Patent Publications WO 01/29052 published Apr. 26, 2001; and WO 01/29141 published Apr. 26, 2001; and (d) nanoporous silica materials and silica-based compounds, such as those compounds disclosed in issued patents U.S. Pat. No. 6,022,812, U.S. Pat. No. 6,037,275, U.S. Pat. No. 6,042,994, U.S. Pat. No. 6,048,804, U.S. Pat. No. 6,090,448, U.S. Pat. No. 6,126,733, U.S. Pat. No. 6,140,254, U.S. Pat. No. 6,204,202, U.S. Pat. No. 6,208,014, and pending applications Ser. Nos. 09/046,474, 09/046,473, 09/111,084, 09/360,131, 09/378,705, 09/234,609, 09/379,866, 09/141,287, 09/379,484, 09/392,413, 09/549,659, 09/488,075, 09/566,287, and 09/214,219 all of which are incorporated by reference herein in their entirety and (e) Honeywell HOSP® organosiloxane.

The wafer or substrate may comprise any desirable substantially solid material. Particularly desirable substrates would comprise glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers such as polyimides. In more preferred embodiments, the substrate comprises a material common in the packaging and circuit board industries such as silicon, copper, glass, or a polymer.

Substrate layers contemplated herein may also comprise at least two layers of materials. One layer of material comprising the substrate layer may include the substrate materials previously described. Other layers of material comprising the substrate layer may include layers of polymers, monomers, organic compounds, inorganic compounds, organometallic compounds, continuous layers and nanoporous layers.

The substrate layer may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer.

### EXAMPLES

### Example 1

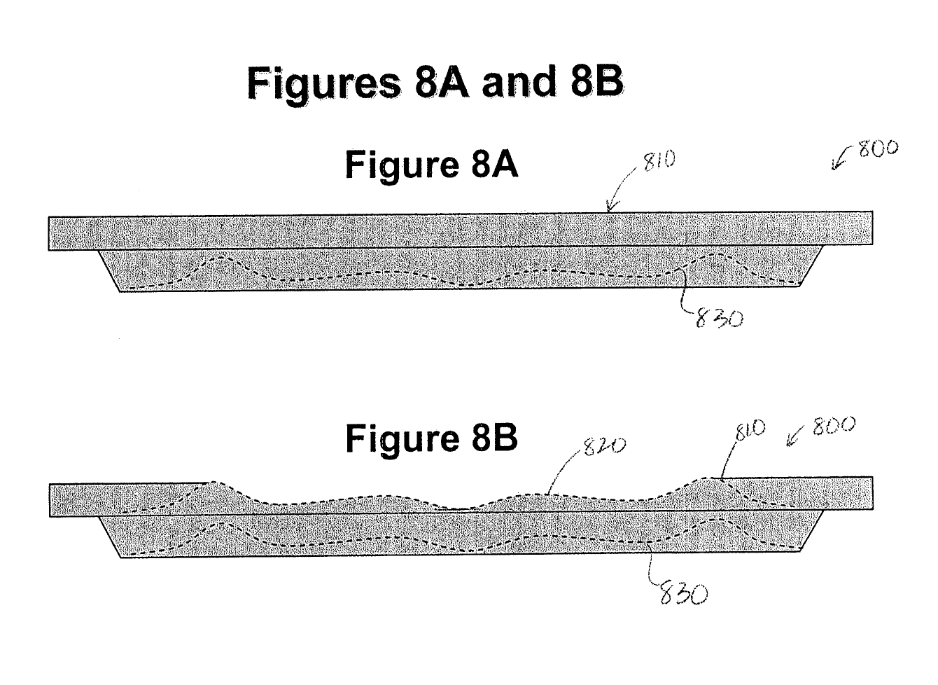

An AMAT 200 mm Endura 5500 PVD system was utilized for this set of experiments wherein the target comprises an aluminum target material. A general method 900 for utilizing one of these systems is shown in FIG. 9, where a target-to-wafer spacing calibration is completed 910, followed by various target burn-in steps 920 at different power levels. A film is deposited from sputtering target atoms 930, which is followed by a film characterization step 940. In some embodiments, a target erosion profile is collected 950. Silicon wafers that are utilized in this study are 1 k SiO₂ wafers.

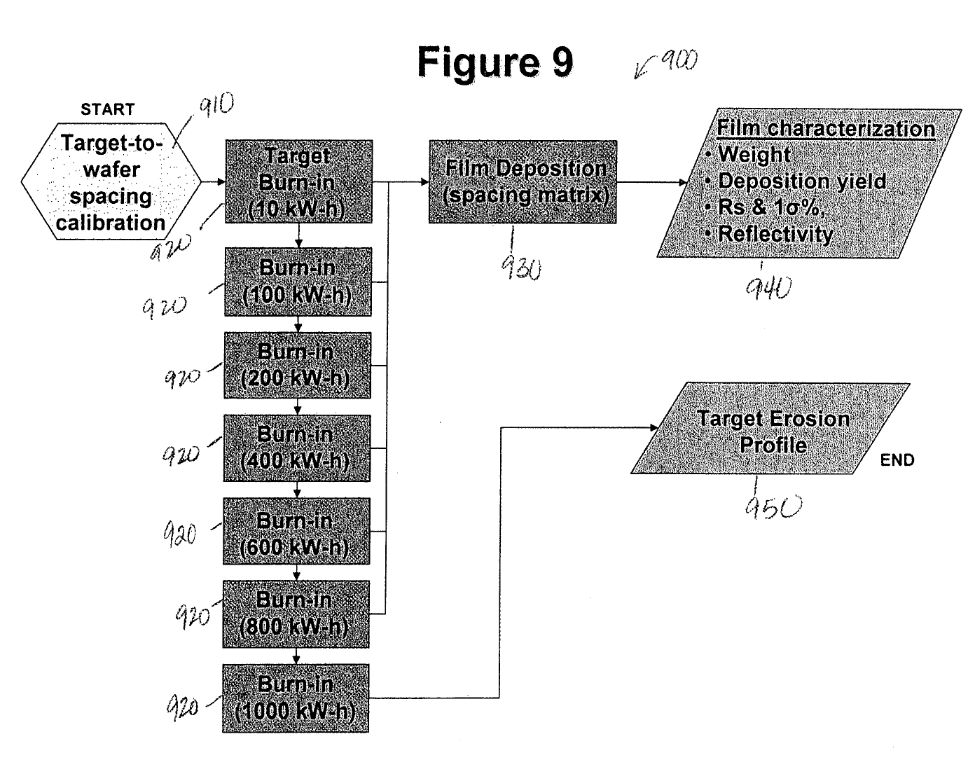

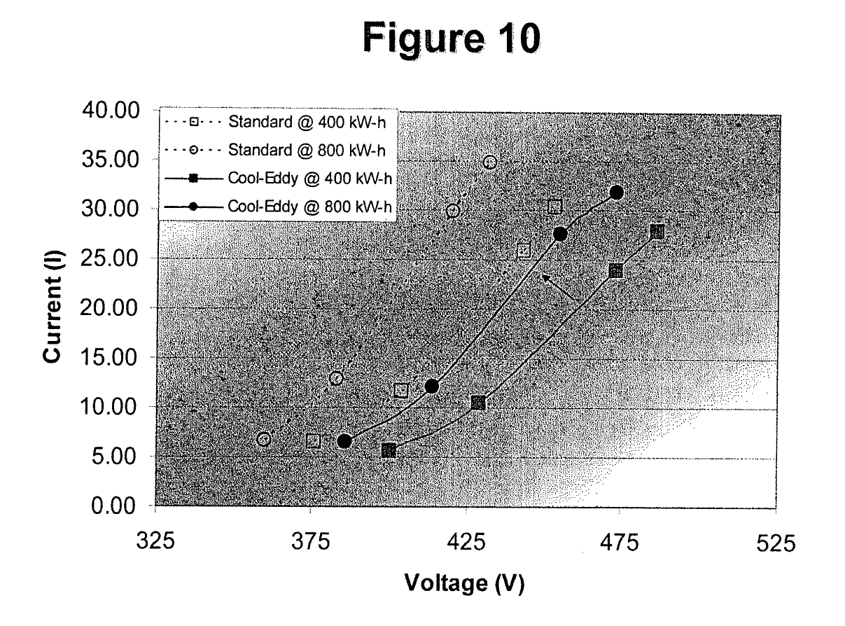

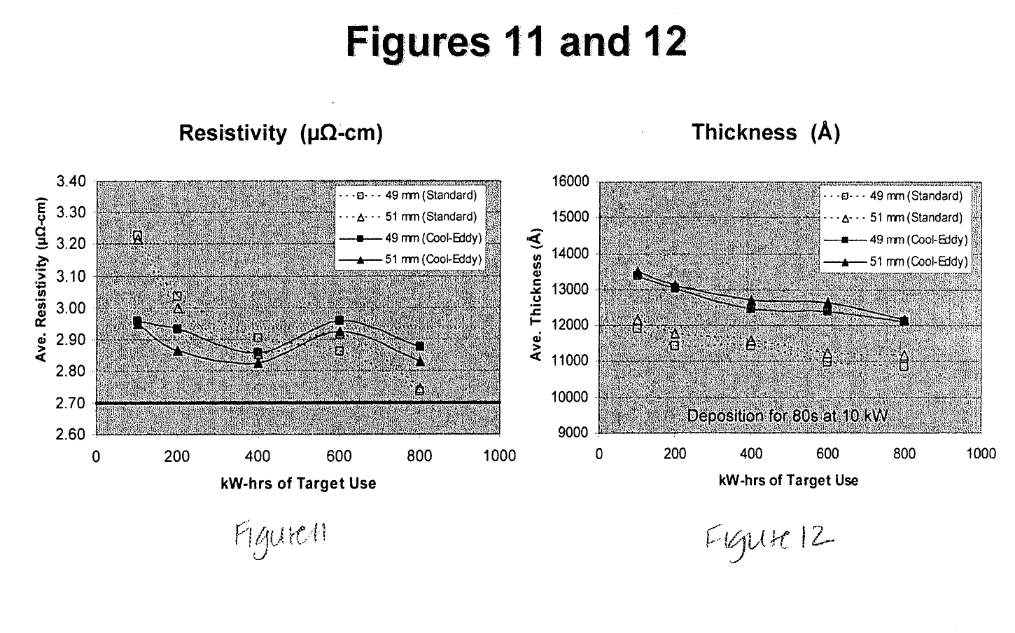

FIG. 10 shows current and voltage data for a contemplated target. This graph is significant, because it shows that contemplated targets, herein called “Cool-Eddy” can operate at higher voltages because of increased target resistance. FIGS. 11 and 12 shows resistivity and film thickness data, respectively, versus the length of time in kW-hours of target use. The resistivity fluctuation is largely due to the varying substrate temperature and the degree of surface oxidation during the chamber opening. The values, however, are within the expected range.

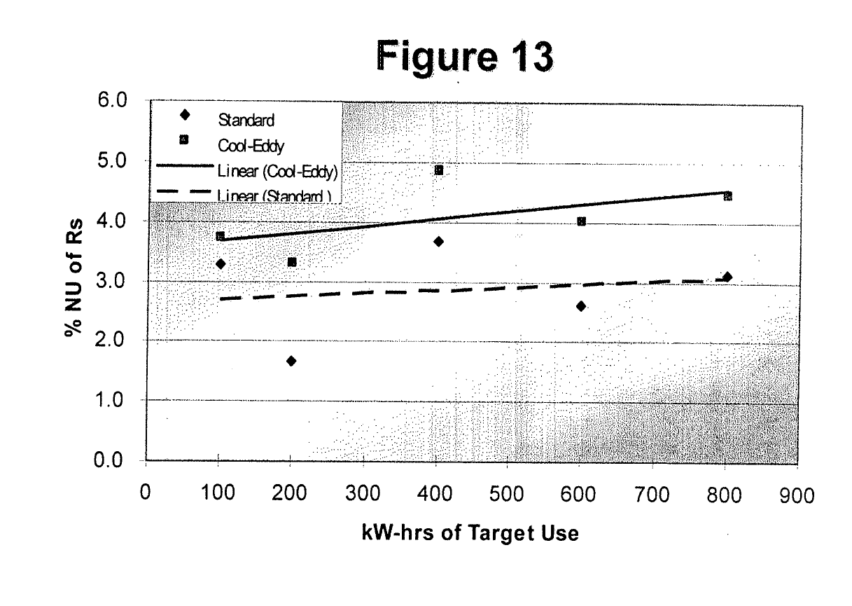

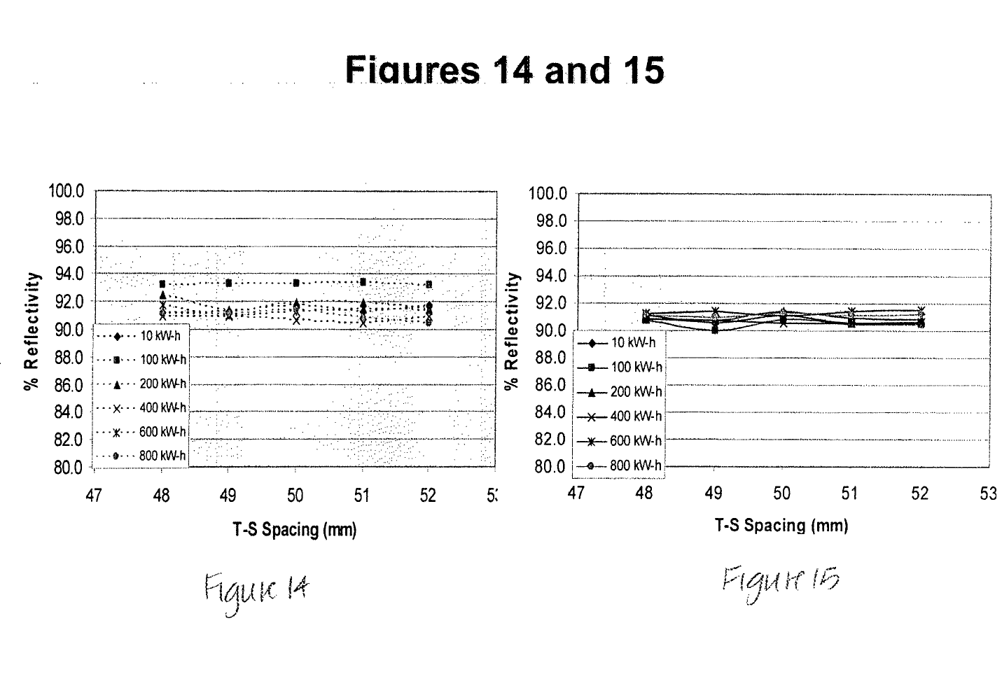

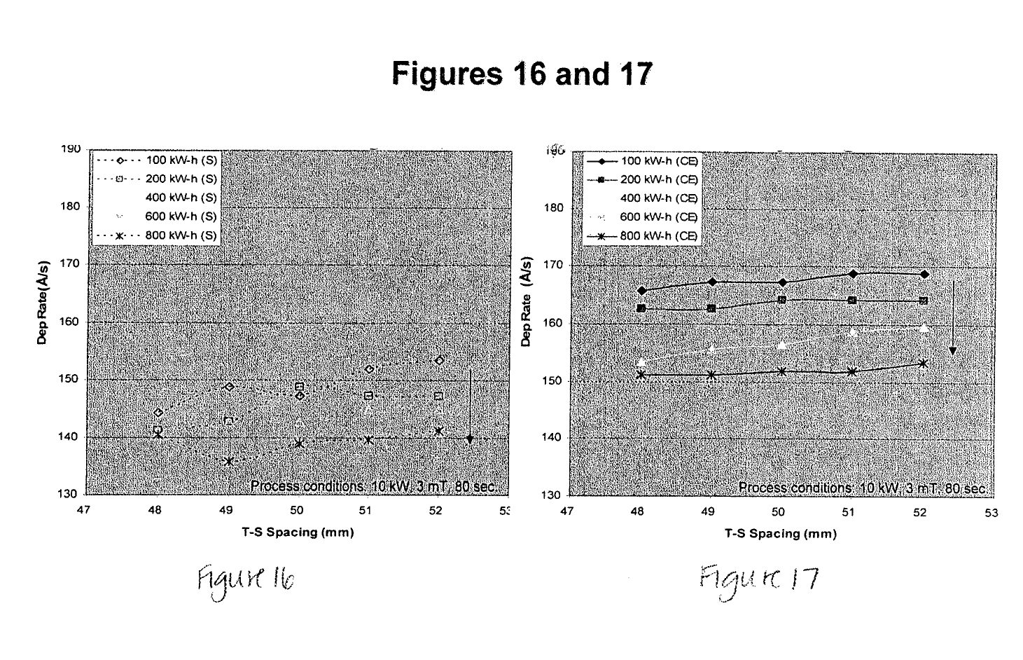

FIG. 13 shows the film uniformity versus the target life for various targets. As shown, the film non-uniformity (1σ % NU Rs) shows an increasing trend. The contemplated targets (“cool-eddy”) target shows larger % NU. Possible causes of these trends are non-optimal T-S spacing and changing plasma profile with target thickness. FIGS. 14 and 15 show reflectivity versus T-S spacing for a conventional target and a contemplated target. The fundamental film property was not affected, since film reflectivity does not vary with spacing. There is a slight variation with target life that can be attributed to different substrate temperatures and oxidation.

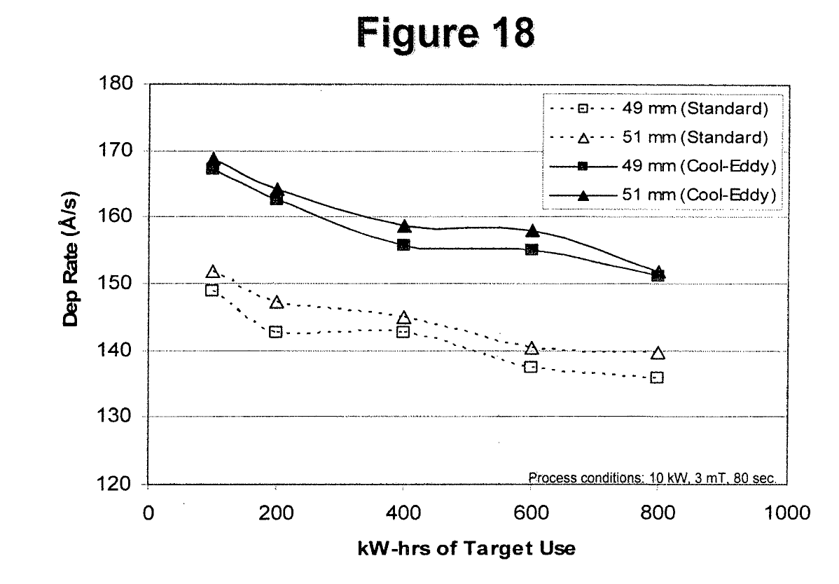

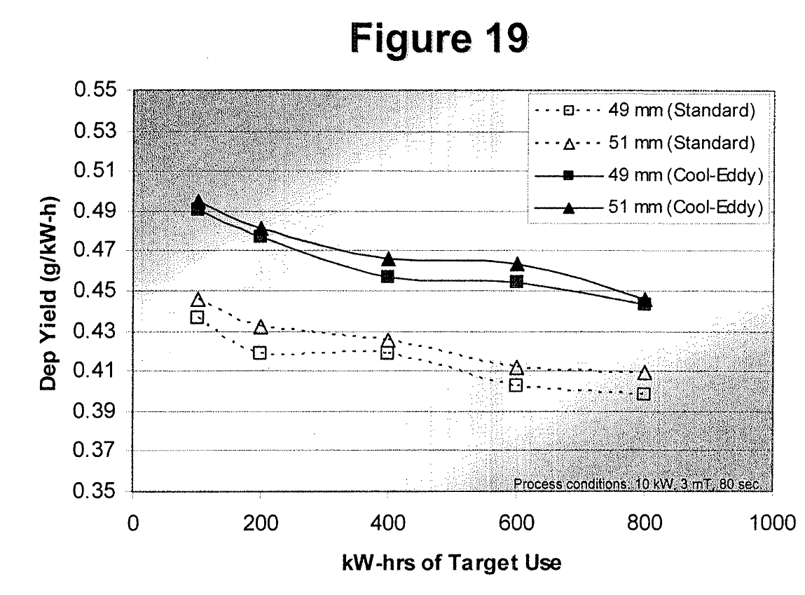

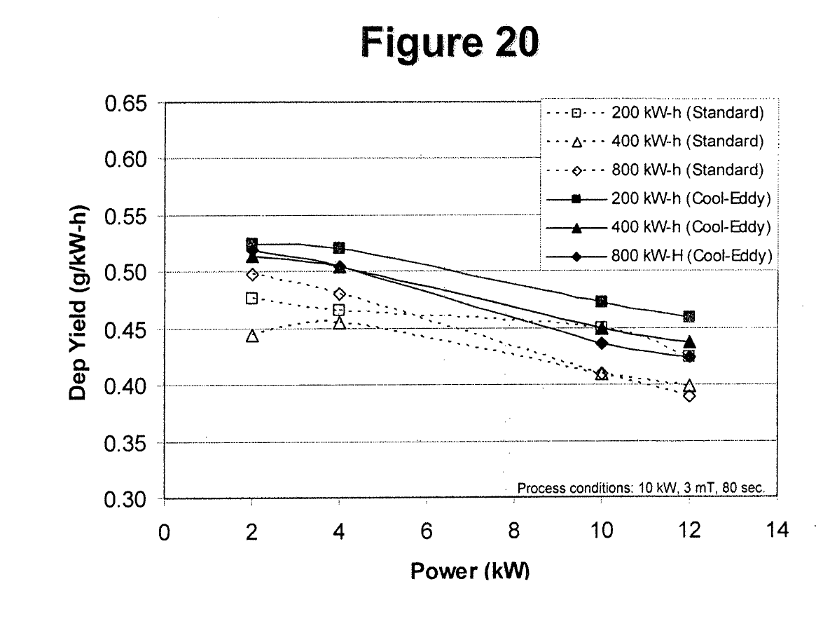

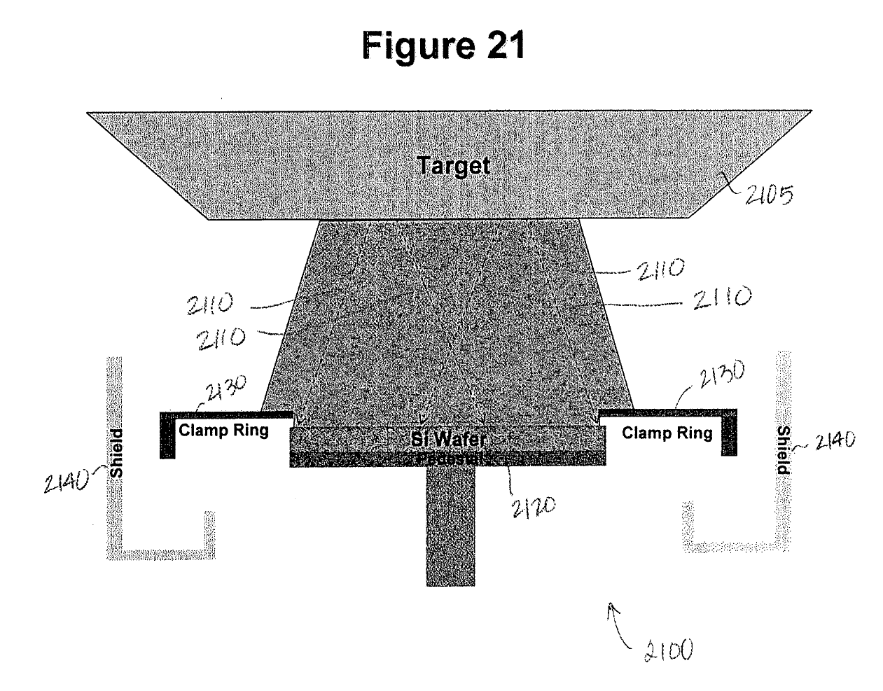

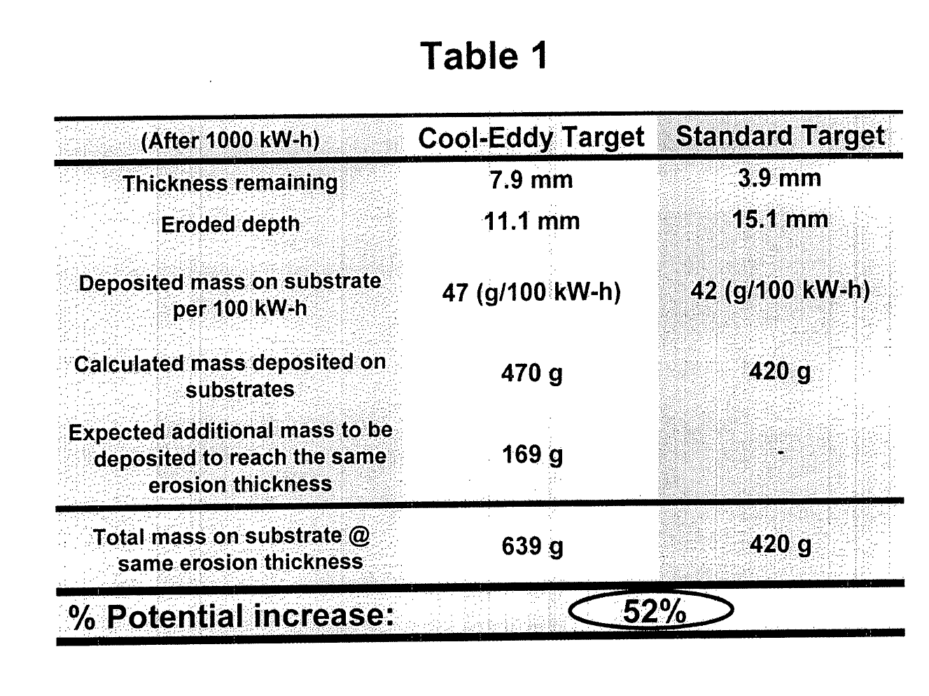

FIGS. 16 and 17 show the deposition rate versus T-S spacing at various stages of a target's life for both conventional and contemplated targets. It should be noted that the effective sputtering yield decreases with the target life, because the fraction of re-deposition increases with the deepening erosion groove. Power compensation is thus required to maintain the same deposition rate as the target erodes. Re-deposition is the major factor in reducing the deposition rate with target erosion. Therefore, as shown in the Figures, the deposition rate decreases strongly with the target usage. But, the contemplated “cool-eddy” target shows 10% higher deposition rate than conventional targets and less variation in deposition rate with spacing (improved plasma distribution). The deposition rate shows an increasing trend with increasing spacing also. FIG. 18 shows additional data for deposition rate versus target life, and FIG. 19 shows the deposition yield versus target erosion. FIG. 20 adds additional information for contemplated targets by showing the deposition rate versus power for standard and contemplated targets. The deposition yield decreases with increasing power, due to deeper ion penetration with increasing operating voltage. There is a larger fraction of Ar-ion energy consumed in the bulk of the target.

Deposition yield, or Y (which equals g/kW-h/wafer), is the actual number of atoms or molecules landing on the wafer. It is affected by system design, magnet configuration, T-S spacing, erosion groove, pressure, target material and target design. It is desirable to have a target that deposits more materials on the wafer than on the chamber side-walls, which can be achieved by making a target that erodes in wider track by reducing eddy-current, increasing target resistance or improving collimation via grain refinement.

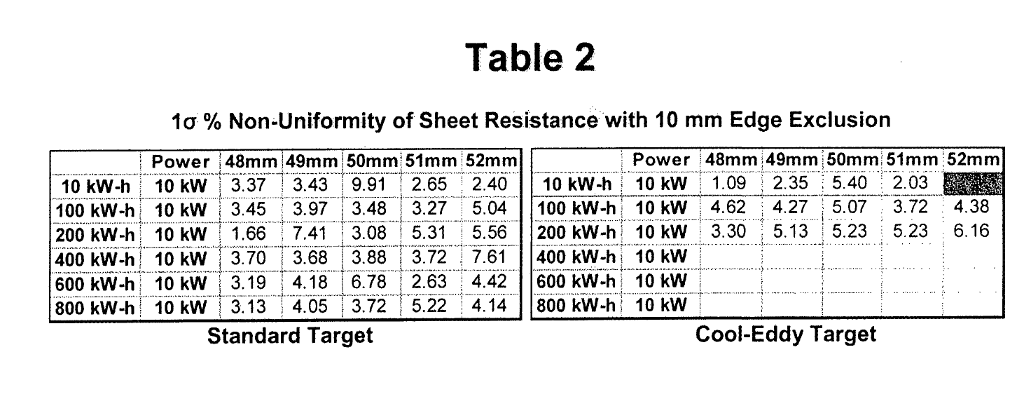

FIG. 21 shows a schematic of a sputtering apparatus 2100 utilizing a contemplated target 2105. It is useful to note that the deposition profile 2110 widens with the use of contemplated targets 2105, and thus leads to deposition on the surface 2120, the clamp rings 2130 and shields 2140. A clamp-less chuck may be utilized to improve film uniformity.

Table 1 shows a summary of the properties of conventional targets versus some of those contemplated herein. Table 2 shows the data collected for the spacing matrix study.

Thus, specific embodiments and applications of target designs and related methods for increased resistivity and/or resistance, reduced Eddy currents and enhanced cooling have been disclosed. It should be apparent, however, to those skilled in the art that many more modifications besides those already described are possible without departing from the inventive concepts herein. The inventive subject matter, therefore, including the claims is not to be restricted except in the spirit of the specification disclosed herein. Moreover, in interpreting the specification and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A sputtering target, comprising:
a target surface component comprising a target material;
a core backing component having a coupling surface and a back surface, wherein the coupling surface is coupled to the target surface component; and
at least one surface area feature coupled to or located in the back surface of the core backing component, wherein the surface area feature increases the resistance, resistivity or a combination thereof of the core backing component.

2. The sputtering target of claim 1, wherein the target material comprises a metal, a metal alloy or a combination thereof.

3. The sputtering target of claim 2, wherein the metal or metal alloy comprises a transition metal.

4. The sputtering target of claim 3, wherein the transition metal comprises copper, aluminum, tantalum or titanium.

5. The sputtering target of claim 1, wherein the target material and the core backing component comprise the same material.

6. The sputtering target of claim 1, wherein the at least one surface area feature comprises at least one altered microstructure, at least one microgroove, at least one slit, at least one crack, at least one erosion profile modification and combinations thereof.

7. The sputtering target of claim 6, wherein the at least one altered microstructure comprises an alloy on the back surface of the core backing component, at least one deformation to the core backing component, at least one additional material to the back surface of the core backing component, or a combination thereof.

8. The sputtering target of claim 7, wherein the at least one additional material to the back surface of the core backing component comprises a material formed by electroplating, ion implantation, vapor deposition, mechanical alloying or a combination thereof.

9. The sputtering target of claim 7, wherein the at least one deformation to the core backing component is created by a shot peening process.

10. The sputtering target of claim 1, wherein the resistance, resistivity or a combination thereof of the core backing component is increased, as compared with a conventional core backing component.

11. The sputtering target of claim 10, wherein the resistance, resistivity or a combination thereof of the core backing component is increased by at least 10% as compared with a conventional core backing component.

12. The sputtering target of claim 11, wherein the resistance, resistivity or a combination thereof of the core backing component is increased by at least 50% as compared with a conventional core backing component.

13. The sputtering target of claim 1, wherein the target is monolithic.

14. A sputtering target assembly, comprising:
a target surface component comprising a target material;
a core backing component having a coupling surface and a back surface, wherein the coupling surface is coupled to the target surface component; and
at least one surface area feature coupled to or located in the back surface of the core backing component, wherein the surface area feature comprises a subtractive feature, an additive feature or a combination thereof.

15. The sputtering target assembly of claim 14, wherein the subtractive feature, the additive feature or the combination thereof increases the resistance of the core backing component as compared to a conventional core backing component.

16. The sputtering target assembly of claim 15, wherein the subtractive feature or the additive feature comprises a convex feature, a concave feature or a combination thereof.

17. A method of forming a sputtering target, comprising:
providing a target surface component comprising a surface material;
providing a core backing component comprising a backing material and having a coupling surface and a back surface;
providing at least one surface area feature coupled to or located in the back surface of the core backing component, wherein the surface area feature increases the resistance, resistivity or a combination thereof of the core backing component; and
coupling the surface target component to the coupling surface of the core backing component.

18. The method of claim 17, wherein the target material comprises a metal, a metal alloy or a combination thereof.

19. The method of claim 18, wherein the metal or metal alloy comprises a transition metal.

20. The method of claim 19, wherein the transition metal comprises copper, aluminum, tantalum or titanium.

21. The method of claim 17, wherein the target material and the core backing component comprise the same material.

22. The method of claim 17, wherein the at least one surface area feature comprises at least one altered microstructure, at least one microgroove, at least one slit, at least one crack, at least one erosion profile modification and combinations thereof.

23. The method of claim 22, wherein the at least one altered microstructure comprises an alloy on the back surface of the core backing component, at least one deformation to the core backing component, at least one additional material to the back surface of the core backing component, or a combination thereof.

24. The method of claim 23, wherein the at least one additional material to the back surface of the core backing component comprises a material formed by electroplating, ion implantation, vapor deposition, mechanical alloying or a combination thereof.

25. The method of claim 23, wherein the at least one deformation to the core backing component is created by a shot peening process.

26. The method of claim 17, wherein the resistance, resistivity or a combination thereof of the core backing component is increased as compared with a conventional core backing component.

27. The method of claim 26, wherein the resistance, resistivity or a combination thereof of the core backing component is increased by at least 10% as compared with a conventional core backing component.

28. The method of claim 27, wherein the resistance, resistivity or a combination thereof of the core backing component is increased by at least 50% as compared with a conventional core backing component.
